(19) United States
(12) Patent Application Publication
(10) Pub. No.: US 2026/0333732 A1
(43) Pub. Date: Oct. 22, 2026

(54) METHOD FOR FABRICATING A SEMICONDUCTOR DEVICE

(71) Applicant: UNITED MICROELECTRONICS CORP., Hsin-Chu City (TW)

(72) Inventors: Wei-Hsuan Chang, Tainan City (TW); Ming-Hua Tsai, Tainan City (TW); Chin-Chia Kuo, Tainan City (TW)

(73) Assignee: UNITED MICROELECTRONICS CORP., Hsin-Chu City (TW)

(21) Appl. No.: 19/723,031

(22) Filed: Jun. 29, 2026

Related U.S. Application Data
(63) Continuation of application No. 18/237,420, filed on Aug. 24, 2023.

(30) Foreign Application Priority Data
Jul. 6, 2023 (TW) 112125232

(51) Int. Cl. H10D 30/01; H10D 30/60; H10D 62/83; H10D 64/01; H10D 64/27; H10D 64/62

(52) U.S. Cl. CPC H10D 30/0212; H10D 30/021; H10D 30/022; H10D 30/601; H10D 30/603; H10D 30/605; H10D 62/83; H10D 64/0112; H10D 64/514; H10D 64/516; H10D 64/62

(57) ABSTRACT

A method for forming a semiconductor device is disclosed. A substrate having a channel region and a heavily doped region disposed therein is provided. A gate oxide layer is formed over the channel region. A gate electrode is formed over the gate oxide layer, and a spacer is formed on a sidewall of the gate electrode. A portion of the gate oxide layer extending beyond an edge of the spacer forms a gate oxide extension portion. A first portion of the gate oxide extension portion is removed while leaving a second portion thereof intact to expose a portion of the heavily doped region. A silicide layer is then formed on the exposed portion of the heavily doped region using the second portion of the gate oxide extension portion as a salicide block.

### CROSS REFERENCE TO RELATED APPLICATIONS

This application is a continuation application of U.S. Application No. 18/237,420, filed on Aug. 24th, 2023. The content of the application is incorporated herein by reference.

### BACKGROUND OF THE INVENTION

### 1. FIELD OF THE INVENTION

The invention relates to the field of semiconductor technology, in particular to a structure and a manufacturing method of a semiconductor device.

### 2. DESCRIPTION OF THE PRIOR ART

Self-aligned silicide (salicide) process has been utilized to fabricate silicide materials for reducing the sheet resistance of the source/drain region. A source/drain region is first formed. A metal layer comprised of cobalt, titanium, or nickel is disposed on the source/drain region. A rapid thermal process (RTP) is then performed to make the metal layer react with the silicon of the gate structure and the source/drain region to form a metal silicide.

Typically, a salicide block (SAB) is used in a salicide process to define the region where silicides are being formed. For instance, a salicide block composed of nitrides is deposited on a semiconductor substrate before the formation of metal layer, and a portion of the salicide block is etched away to expose the source/drain region on the semiconductor substrate.

### SUMMARY OF THE INVENTION

It is one object of the present invention to provide an improved semiconductor device and its manufacturing method to solve the deficiencies or shortcomings of the prior art.

One aspect of the present invention provides a method for forming a semiconductor device. A substrate is provided. A channel region and a heavily doped region are disposed in the substrate. A gate oxide layer is formed over the channel region. A gate electrode is formed over the gate oxide layer. A spacer is formed on a sidewall of the gate electrode. A portion of the gate oxide layer extending beyond an edge of the spacer forms a gate oxide extension portion. A first portion of the gate oxide extension portion is then removed, while leaving a second portion of the gate oxide extension portion intact, thereby exposing a portion of the heavily doped region in the substrate. A silicide layer is then formed on the exposed portion of the heavily doped region using the second portion of the gate oxide extension portion as a salicide block.

According to some embodiments, the step of removing the first portion of the gate oxide extension portion comprises the steps of: forming a photoresist pattern covering the gate electrode, the spacer, and the second portion of the gate oxide extension portion; etching away the first portion of the gate oxide extension portion not covered by the photoresist pattern; and removing the photoresist pattern.

According to some embodiments, the method further comprises the step of: completely removing the second portion of the gate oxide extension portion after the silicide layer is formed.

According to some embodiments, the step of removing the first portion of the gate oxide extension portion comprises: removing the gate oxide extension portion on a first side of the gate electrode entirely, such that the silicide layer formed on the first side extends to a bottom of the edge of the spacer.

According to some embodiments, the gate oxide extension portion is formed by thinning the gate oxide layer during an anisotropic etching process that forms the spacer.

According to some embodiments, the gate oxide extension portion has a thickness less than that of the gate oxide layer underneath the gate electrode.

According to some embodiments, the silicide layer is contiguous with the second portion of the gate oxide extension portion.

According to some embodiments, the silicide layer comprises nickel silicide or cobalt silicide.

According to some embodiments, the gate electrode comprises metal.

According to some embodiments, the method further comprises: forming a first lightly doped drain (LDD) region in the substrate on a side of the channel region, wherein the first LDD region and the heavily doped region collectively form a diffusion region, wherein the heavily doped region is formed within the first LDD region, and wherein the second portion of the gate oxide extension portion partially overlaps with the heavily doped region.

According to some embodiments, the method further comprises: forming a second lightly doped drain (LDD) region in the substrate on a side of the channel region, wherein the first LDD region is formed within the second LDD region.

According to some embodiments, the substrate is a silicon substrate having a first conductivity type, and the channel region and the diffusion region are disposed within an ion well of the first conductivity type, wherein the heavily doped region and the first LDD region have a second conductivity type opposite to the first conductivity type.

According to some embodiments, the first conductivity type is P type and the second conductivity type is N type.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view of a semiconductor device according to an embodiment of the present invention.

FIG. 2 to FIG. 4 illustrate a method of forming the semiconductor device in FIG. 1.

FIG. 5 illustrates that the gate oxide extension portions on both sides of the gate of the semiconductor device are removed after the silicide layer is formed.

FIG. 6 illustrates a semiconductor device with an asymmetric diffusion region.

FIG. 7 illustrates a semiconductor device with asymmetric gate oxide extension portions.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

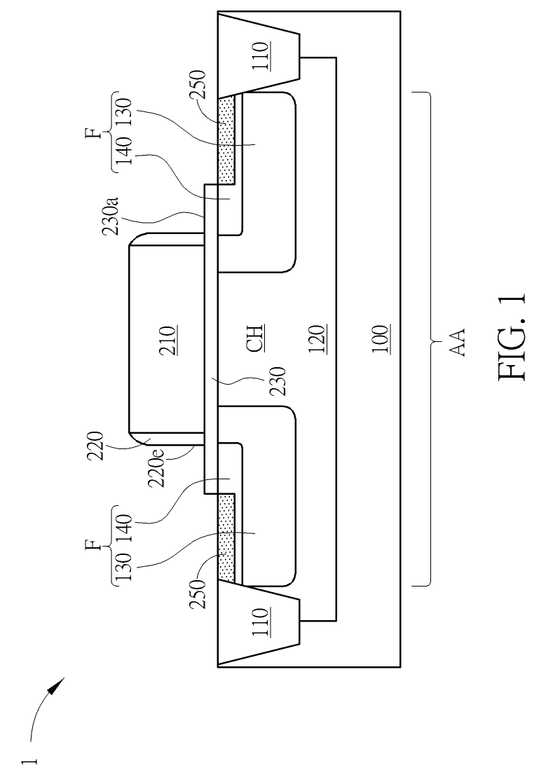

Please refer to FIG. 1, which is a schematic cross-sectional view of a semiconductor device according to an embodiment of the present invention. As shown in FIG. 1, a semiconductor device 1, such as a medium-voltage or high-voltage transistor device, includes a substrate 100, such as a semiconductor substrate. According to an embodiment of the present invention, a shallow trench isolation structure 110 is disposed in the substrate 100 to define an active area AA. According to an embodiment of the present invention, a channel region CH is disposed in the substrate 100. According to an embodiment of the present invention, a diffusion region F is disposed in the substrate 100 on one side of the channel region CH. The diffusion region F includes a lightly doped drain (LDD) region 130 and a heavily doped region 140 located in the lightly doped drain region 130. In other embodiments, the semiconductor device 1 may be a low-voltage transistor device.

According to an embodiment of the present invention, for example, the substrate 100 is a silicon substrate having a first conductivity type. For example, the first conductivity type is P type. For example, the substrate 100 is a P-type silicon substrate. According to an embodiment of the present invention, for example, an ion well 120 of the first conductivity type, for example, a P-type well, is provided in the substrate 100, and both the channel region CH and the diffusion region F are arranged in the ion well 120. The heavily doped region 140 and the lightly doped drain region 130 have a second conductivity type opposite to the first conductivity type. According to an embodiment of the present invention, for example, the second conductivity type is N type. The above electrical properties are only for illustration, and those skilled in the art should understand that the semiconductor device 1 of the present invention can be an NMOS device or a PMOS device.

According to an embodiment of the present invention, a gate electrode 210 is disposed above the channel region CH, wherein the gate electrode 210 partially overlaps with the lightly doped drain region 130. According to an embodiment of the present invention, the gate electrode 210 may include metal, such as copper, aluminum, tungsten, titanium, titanium nitride, or any combination thereof. According to an embodiment of the present invention, the gate electrode 210 may include polysilicon.

According to an embodiment of the present invention, spacers 220 are disposed on the sidewalls of the gate electrode 210. According to an embodiment of the present invention, for example, the spacers 220 may include silicon nitride.

According to an embodiment of the present invention, the semiconductor device 1 further includes a gate oxide layer 230 disposed between the gate electrode 210 and the channel region CH, between the gate electrode 210 and the lightly doped drain region 130, and between the spacer 220 and the lightly doped drain region 130. According to an embodiment of the present invention, the thickness of the gate oxide layer 230 is at least 80 angstroms. According to an embodiment of the present invention, the thickness of the spacer 220 is at least 15 nm.

According to an embodiment of the present invention, the semiconductor device 1 further includes a gate oxide extension portion 230a protruding from the edge 220e of the spacer 220 and partially overlapping with the heavily doped region 140. According to an embodiment of the invention, the gate oxide extension portion 230a is thinner than the gate oxide layer 230. According to an embodiment of the present invention, the thickness of the gate oxide extension portion 230a is at least 30 angstroms. According to an embodiment of the present invention, the gate oxide extension portion 230a protrudes from the edge 220e of the spacer 220 by at least 30 nm.

According to an embodiment of the present invention, the semiconductor device 1 further includes a silicide layer 250 disposed on the heavily doped region 140 not covered by the gate oxide extension portion 230a, and the silicide layer 250 is spaced apart from the edge 220e of the spacer 220. According to an embodiment of the present invention, the silicide layer 250 may include nickel silicide or cobalt silicide, but is not limited thereto. According to an embodiment of the present invention, the silicide layer 250 is contiguous with the gate oxide extension portion 230a.

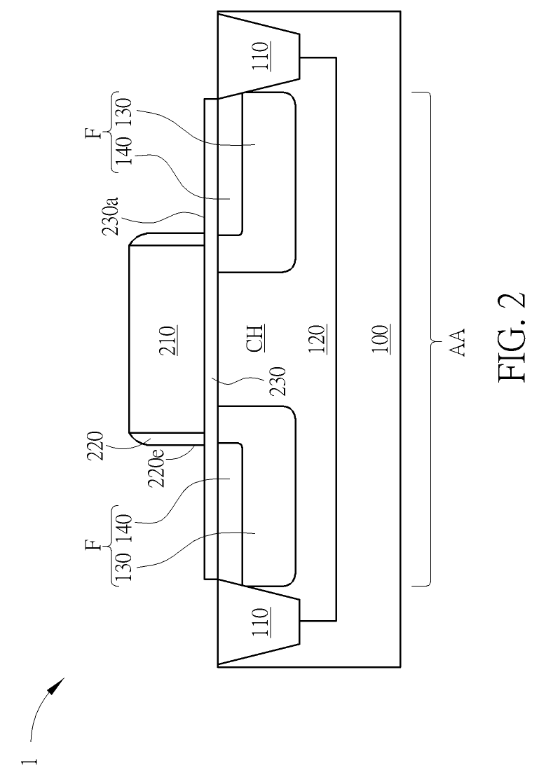

FIG. 2 to FIG. 4 illustrate a method of forming the semiconductor device in FIG. 1. First, as shown in FIG. 2, a substrate 100, such as a semiconductor substrate, is provided. According to an embodiment of the present invention, a shallow trench isolation structure 110 is formed in the substrate 100 to define an active area AA. According to an embodiment of the present invention, a channel region CH is formed in the substrate 100. According to an embodiment of the present invention, the diffusion region F is formed in the substrate 100 on one side of the channel region CH by ion implantation process. According to an embodiment of the present invention, for example, the diffusion region F includes a lightly doped drain region 130 and a heavily doped region 140 located in the lightly doped drain region 130.

According to an embodiment of the present invention, for example, the substrate 100 is a silicon substrate having a first conductivity type. For example, the first conductivity type is P type. For example, the substrate 100 is a P-type silicon substrate. According to an embodiment of the present invention, for example, an ion well 120 of the first conductivity type, for example, a P-type well, is formed in the substrate 100, and both the channel region CH and the diffusion region F are formed in the ion well 120. The heavily doped region 140 and the lightly doped drain region 130 have a second conductivity type opposite to the first conductivity type. According to an embodiment of the present invention, for example, the second conductivity type is N type.

According to an embodiment of the present invention, a gate oxide layer 230 is then formed on the channel region CH, and is disposed on the channel region CH, the lightly doped drain region 130 and the heavily doped region 140. According to an embodiment of the present invention, the thickness of the gate oxide layer 230 is at least 80 angstroms. According to an embodiment of the present invention, for example, the gate oxide layer 230 may be formed by thermal oxidation or chemical vapor deposition.

According to an embodiment of the present invention, a gate electrode 210 is then formed above the channel region CH, wherein the gate electrode 210 partially overlaps with the lightly doped drain region 130. According to an embodiment of the present invention, the gate electrode 210 may include metal, such as copper, aluminum, tungsten, titanium, titanium nitride, or any combination thereof. According to an embodiment of the present invention, the gate electrode 210 may include polysilicon. Next, spacers 220 are formed on the sidewalls of the gate electrode 210. According to an embodiment of the present invention, for example, the spacers 220 may include silicon nitride.

The anisotropic dry etching performed during the formation of the spacers 220 will slightly etch away the gate oxide layer 230 that is not covered by the gate electrode 210 and the spacers 220, forming a gate oxide extension portion 230a protruding from the edge 220e of the spacers 220. According to an embodiment of the invention, the gate oxide extension portion 230a is thinner than the gate oxide layer 230. According to an embodiment of the present invention, the thickness of the gate oxide extension portion 230a is at least 30 angstroms.

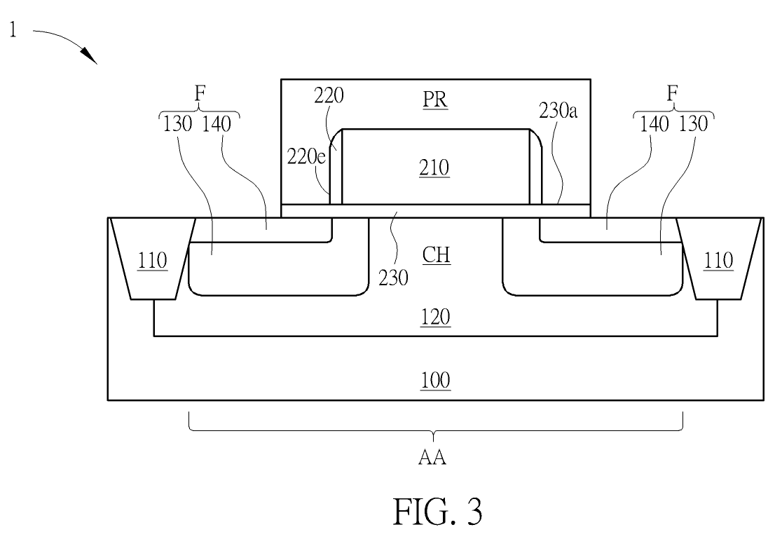

As shown in FIG. 3, a lithography process is then performed to form a photoresist pattern PR on the substrate 100 to cover the gate electrode 210, the spacers 220 and part of the gate oxide extension portion 230a. Next, an etching process, such as a dry etching process, is performed to etch away the gate oxide extension portion 230a not covered by the photoresist pattern PR to expose part of the heavily doped region 140. Subsequently, the photoresist pattern PR is removed.

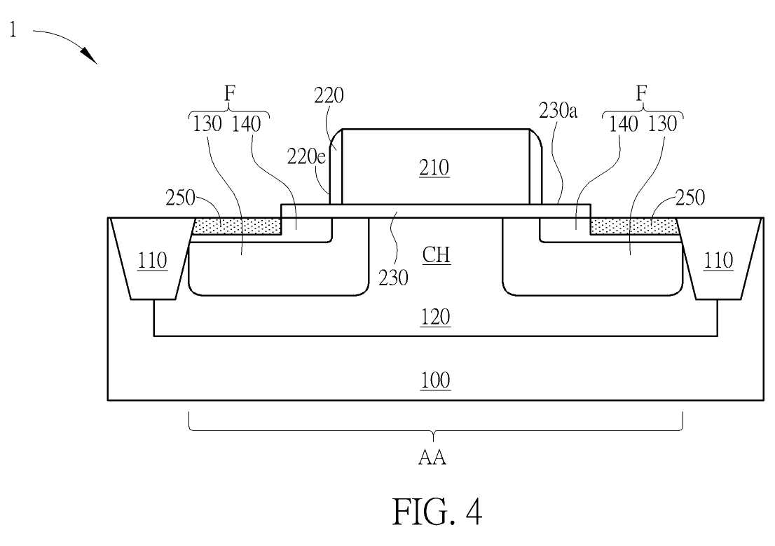

As shown in FIG. 4, a salicide process is then performed to form a silicide layer 250 on the heavily doped region 140, and the silicide layer 250 is spaced apart from the edge 220e of the spacer 220. In the aforementioned salicide process, the gate oxide extension portion 230a is used as a salicide block layer. It is advantageous to use the invention because the steps of depositing and patterning a salicide block layer and the photo masks related to the formation of the salicide block layer can be saved. For example, the aforementioned salicide process may include: depositing a metal layer on the substrate 100, such as metals such as cobalt, titanium or nickel, and then performing rapid thermal treatment to make the metal layer react with silicon in the gate structure and the source/drain region so as to form a metal silicide, and then the incompletely reacted metal layer is removed.

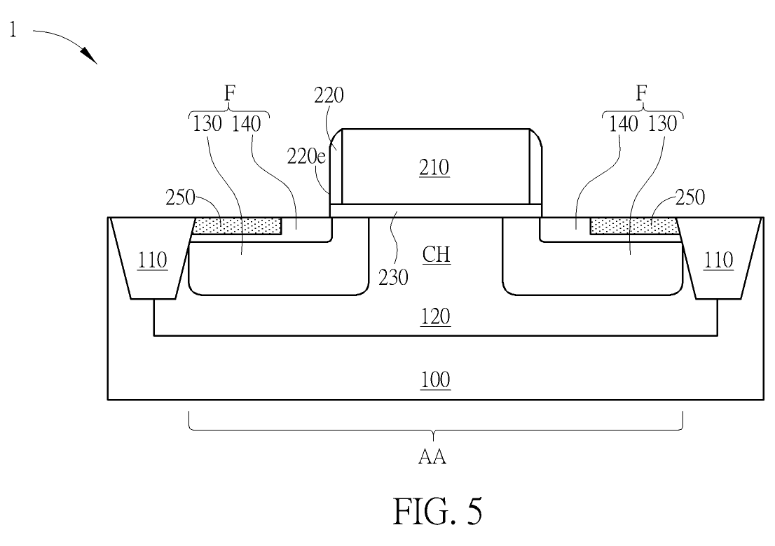

The semiconductor device 1 provided by the present disclosure includes: a substrate 100; a channel region CH, disposed in the substrate 100; a diffusion region F, disposed in the substrate 100 on one side of the channel region CH, and the diffusion region F includes a lightly doped drain region 130 and a heavily doped region 140 located in the lightly doped drain region; the gate electrode 210 is arranged above the channel region CH, wherein the gate electrode 210 partially overlaps with the lightly doped drain region 130. A spacer 220 is arranged on the sidewall of the gate electrode 210. A gate oxide layer 230 is arranged between the gate electrode 210 and the channel region CH, between the gate electrode 210 and the lightly doped drain region 130, and between the spacer 220 and the lightly doped drain region 130. A silicide layer 250 is disposed on the heavily doped region 140 and spaced apart from the edge 220e of the spacer 220. According to some embodiments of the present invention, the semiconductor device 1 may further include a gate oxide extension portion 230a protruding from the edge 220e of the spacer 220 and partially overlapping the heavily doped region 140. In some embodiments, as shown in FIG. 5, the gate oxide extension portions 230a on both sides of the gate electrode 210 may be removed after the silicide layer 250 is formed.

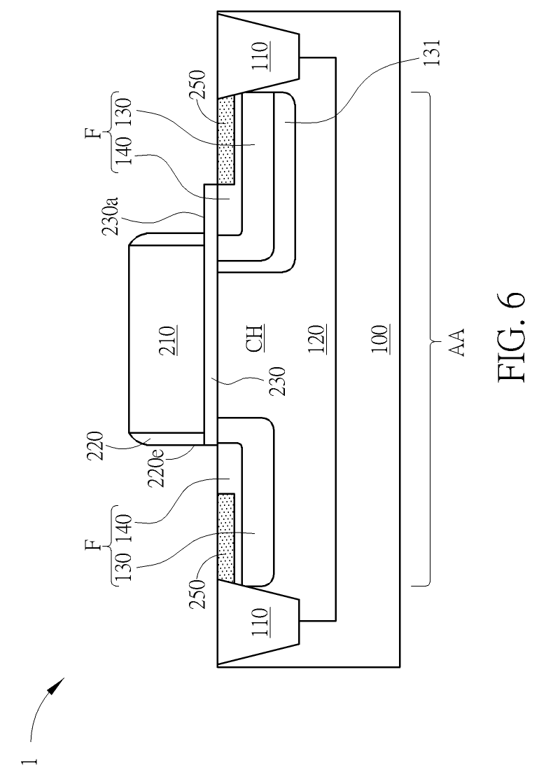

The diffusion region F of the semiconductor device 1 in FIG. 1 is a left-right symmetrical structure. However, in other embodiments, the diffusion region F may also have a left-right asymmetric structure, as shown in FIG. 6. In FIG. 6, for example, the diffusion region F on the right further includes a lightly doped drain region 131, and the lightly doped drain region 130 is formed in the lightly doped drain region 131.

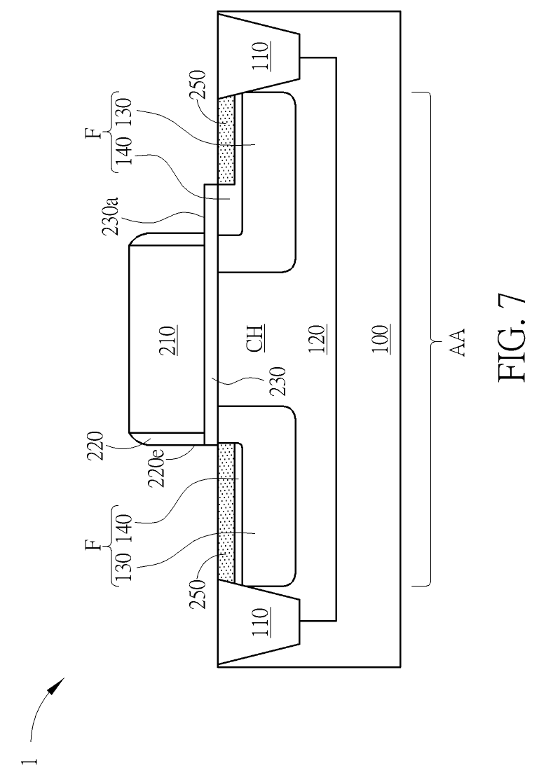

The gate oxide extension portion 230a of the semiconductor device 1 in FIG. 1 is a left-right symmetrical structure. However, in other embodiments, the gate oxide extension portion 230a may also be a left-right asymmetric structure, as shown in FIG. 7. In FIG. 7, for example, the gate oxide extension portion 230a on the left side of the gate electrode 210 is removed, so that the silicide layer 250 on the left side will extend to the bottom of the sidewall 220e of the spacer 220 when the subsequent salicide process is performed.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. A method for forming a semiconductor device, comprising:
providing a substrate having a channel region and a heavily doped region disposed therein;
forming a gate oxide layer over the channel region in the substrate;
forming a gate electrode over the gate oxide layer;
forming a spacer on a sidewall of the gate electrode, wherein a portion of the gate oxide layer extending beyond an edge of the spacer forms a gate oxide extension portion;
removing a first portion of the gate oxide extension portion while leaving a second portion of the gate oxide extension portion intact, thereby exposing a portion of the heavily doped region in the substrate; and
forming a silicide layer on the exposed portion of the heavily doped region using the second portion of the gate oxide extension portion as a salicide block.

2. The method according to claim 1, wherein the step of removing the first portion of the gate oxide extension portion comprises:
forming a photoresist pattern covering the gate electrode, the spacer, and the second portion of the gate oxide extension portion;
etching away the first portion of the gate oxide extension portion not covered by the photoresist pattern; and
removing the photoresist pattern.

3. The method according to claim 1, further comprising:
completely removing the second portion of the gate oxide extension portion after the silicide layer is formed.

4. The method according to claim 1, wherein the step of removing the first portion of the gate oxide extension portion comprises:
removing the gate oxide extension portion on a first side of the gate electrode entirely, such that the silicide layer formed on the first side extends to a bottom of the edge of the spacer.

5. The method according to claim 1, wherein the gate oxide extension portion is formed by thinning the gate oxide layer during an anisotropic etching process that forms the spacer.

6. The method according to claim 1, wherein the gate oxide extension portion has a thickness less than that of the gate oxide layer underneath the gate electrode.

7. The method according to claim 1, wherein the silicide layer is contiguous with the second portion of the gate oxide extension portion.

8. The method according to claim 1, wherein the silicide layer comprises nickel silicide or cobalt silicide.

9. The method according to claim 1, wherein the gate electrode comprises metal.

10. The method according to claim 1, further comprising:
forming a first lightly doped drain (LDD) region in the substrate on a side of the channel region, wherein the first LDD region and the heavily doped region collectively form a diffusion region, wherein the heavily doped region is formed within the first LDD region, and wherein the second portion of the gate oxide extension portion partially overlaps with the heavily doped region.

11. The method according to claim 10, further comprising:
forming a second lightly doped drain (LDD) region in the substrate on a side of the channel region, wherein the first LDD region is formed within the second LDD region.

12. The method according to claim 10, wherein the substrate is a silicon substrate having a first conductivity type, and the channel region and the diffusion region are disposed within an ion well of the first conductivity type, wherein the heavily doped region and the first LDD region have a second conductivity type opposite to the first conductivity type.

13. The method according to claim 12, wherein the first conductivity type is P type and the second conductivity type is N type.
